(19) United States
(12) Patent Application Publication
(10) Pub. No.: US 2016/0103185 A1
(43) Pub. Date: Apr. 14, 2016

(54) ELECTRIFIED VEHICLE BATTERY STATE-OF-CHARGE MONITORING WITH AGING COMPENSATION

(71) Applicant: FORD GLOBAL TECHNOLOGIES, LLC, Dearborn, MI (US)

(72) Inventors: Xiaoguang Chang, Northville, MI (US); Chuan He, Northville, MI (US); Xu Wang, Dearborn, MI (US); Josephine S. Lee, Novi, MI (US)

(21) Appl. No.: 14/513,400

(22) Filed: Oct. 14, 2014

(51) Int. Cl. G01R 31/36

(52) U.S. Cl. CPC G01R 31/3655; G01R 31/3675; G01R 31/3606

(57) ABSTRACT

Determination of an electric vehicle battery state-of-charge (SOC) based on measuring open circuit voltage is subject to error as the relationship changes over time. A method is provided for updating the relationship during aging. A charging current is applied to the battery cell. A favorable charging condition is detected in response to a predetermined charging current. A charging slope vector is compiled during the charging condition comprising a plurality of slope values over respective state-of-charge increments. A plurality of SOC-OCV slope vectors are determined corresponding to a plurality of stored SOC-OCV aging curves, each SOC-OCV slope vector comprising a plurality of slope values over equivalent state-of-charge increments. One of the stored SOC-OCV aging curves is selected having an SOC-OCV slope vector best fitting the charging slope vector for use in converting measured OCV values to battery cell SOC values.

### CROSS REFERENCE TO RELATED APPLICATIONS

Not Applicable.

### STATEMENT REGARDING FEDERALLY SPONSORED RESEARCH

Not Applicable.

### BACKGROUND OF THE INVENTION

The present invention relates in general to battery state-of-charge determination in electric vehicles, and, more specifically, to battery age monitoring to track changes in the relationship between state-of-charge and open circuit voltage. The DC power source (e.g., a battery) and other elements of electric drives for electrified vehicles (e.g., full electric and hybrids) require monitoring in order to maximize efficiency and performance as well as to determine a battery state-of-charge (SOC) to predict remaining driving range under battery power. Common battery types such as lithium ion (Li-Ion) use a large number of individual battery cells stacked together (connected in series and/or parallel) into a battery pack. Besides monitoring the total voltage output by a battery pack, each cell is typically monitored individually to determine their voltage production, current, and other parameters. The temperature of each cell is typically monitored in order to protect against overheating.

It is very challenging to reliably monitor the various battery conditions because of the high-voltage levels involved, the range of intermediate voltages at which respective cells operate within the stack, and the high levels of accuracy required. Various battery monitoring integrated circuit devices have been developed commercially for use in the vehicle environment. Examples of a commercially available battery monitoring IC device include the AD7280A device available from Analog Devices, Inc., of Norwood, Mass., the LTC6804 devices available from Linear Technology Corporation of Milpitas, Calif., and the ISL94212 Multi-Cell Li-Ion Battery Manager available from Intersil Corporation of Milpitas, Calif. A typical component in an electric drive is a Battery Energy Controller Module (BECM) that includes or can be programmed to include various battery management and communication functions in addition to the monitoring functions.

The SOC in particular is a critical parameter to be monitored because it is used to estimate remaining capacity, power capability, and other battery status. Although current measurements can be used to track the value of the SOC, a more accurate method is based on measuring battery cell open circuit voltage (OCV) which correlates to the SOC via a known relationship which is characteristic of each particular battery design. With a Li-ion battery especially, this SOC-OCV curve changes (i.e., drifts) as a result of battery aging and usage. Use of an inaccurate SOC-OCV curve impairs accurate SOC estimation.

### SUMMARY OF THE INVENTION

The present invention uses a piecewise linear model obtained by measuring a charging voltage-vs-SOC curve for comparison with a family of predetermined SOC-vs-OCV aging curves, and picks the one with a best fit as the one most accurately representing the aged condition of the battery or cell.

In one aspect of the invention, a method is provided for monitoring battery cell state-of-charge (SOC) using open circuit voltage (OCV). A charging current is applied to the battery cell. A charging condition is detected in response to a predetermined charging current. A charging slope vector is compiled during the charging condition comprising a plurality of slope values over respective state-of-charge increments. A plurality of SOC-OCV slope vectors are determined corresponding to a plurality of stored SOC-OCV aging curves, each SOC-OCV slope vector comprising a plurality of slope values over equivalent state-of-charge increments. One of the stored SOC-OCV aging curves is selected having an SOC-OCV slope vector best fitting the charging slope vector for use in converting measured OCV values to battery cell SOC values.

### BRIEF DESCRIPTION OF THE DRAWINGS

FIG. 1 is a graph of a family of SOC-OCV curves corresponding to the aging of a particular battery cell, showing how the relationship between open circuit voltage and state-of-charge changes over time.

FIG. 2 is a graph showing an increasing cell voltage during charging together with a portion of an SOC-OCV curve that would accurately characterize the battery cell during an overlapping time.

FIG. 3 is a graph showing a piecewise determination of a charging slope vector.

FIG. 4 is a graph showing a piecewise determination of an SOC-OCV slope vector.

FIG. 5 is a block diagram showing one type of an electric vehicle operating with the present invention.

FIG. 6 is a block diagram showing a multi-cell battery and sensor and controller elements according to one preferred embodiment for implementing the present invention.

FIG. 7 is a flowchart showing one preferred method of the invention.

FIG. 8 is a flowchart showing one preferred method for compiling a charging slope vector.

### DETAILED DESCRIPTION OF PREFERRED EMBODIMENTS

The term “electrified vehicle” as used herein includes vehicles having an electric motor for vehicle propulsion, such as battery electric vehicles (BEV), hybrid electric vehicles (HEV), and plug-in hybrid electric vehicles (PHEV). A BEV includes an electric motor, wherein the energy source for the motor is a battery that is re-chargeable from an external electric grid. In a BEV, the battery is the source of energy for vehicle propulsion. A HEV includes an internal combustion engine and an electric motor, wherein the energy source for the engine is fuel and the energy source for the motor is a battery. In a HEV, the engine is the main source of energy for vehicle propulsion with the battery providing supplemental energy for vehicle propulsion (e.g., the battery buffers fuel energy and recovers kinematic energy in electric form). A PHEV is like a HEV, but the PHEV has a larger capacity battery that is rechargeable from the external electric grid. In a PHEV, the battery is the main source of energy for vehicle propulsion until the battery depletes to a low energy level, at which time the PHEV operates like a HEV for vehicle propulsion.

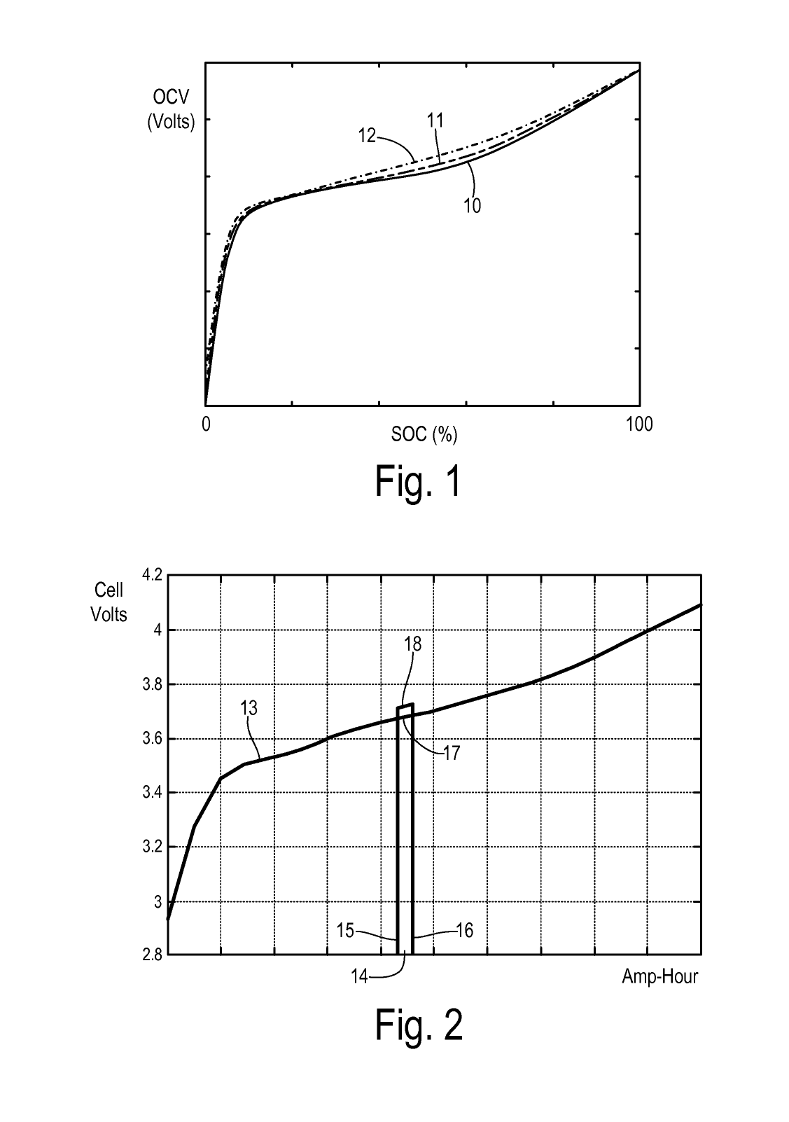

FIG. 1 shows a family of SOC-OCV curves showing a drift due to aging for a fresh battery corresponding to curve 10, a slightly aged battery corresponding to curve 11, and a more significantly aged battery corresponding to curve 12. Each such curve can be obtained by rigorous laboratory testing of a sample battery. Since the actual condition of a battery during vehicle use has not been available, known electric vehicles have not been able to choose the most appropriate curve during vehicle service.

Cell voltage can be modeled using a simple R model (especially when current is constant) according to the formula:

vₜ(t)=v_{oc}(t)+i(t)R(T,SOC)

where R(T,SOC) is the internal resistance, which is a function of temperature and SOC. In the equation, the charging current is positive and discharge current is negative. During charging of the battery, the increase in charge as measured in Amp-Hours (e.g., measured by integrating the charging current, ∫ₜ_{₀}^{t}^{⁰}^{+t}i·dt) gives the corresponding change in SOC. If the change in SOC (i.e., SOC₁-SOC₀) is small enough, then both the current i(t) and R are substantially constant. This means that during charging, the a cell voltage vs. SOC curve would locally have the same slope as the actual SOC-OCV curve SOC=f(v_{oc}) for the cell. Based on these properties, the invention employs a method based on the shape of cell voltage vs. SOC during constant current charging to identify an OCV-SOC curve SOC=f*(v_{oc}) from a family of curves SOC=fᵢ(v_{oc}) stored in a predefined curve bank. For the slope measurements, a calibratable threshhold for the increment in the SOC may be about 0.1 of the battery cell capacity, for example.

FIG. 2 shows a charging profile 13 wherein the cell voltage increases over time as the total charge (i.e., total amps×hours) accumulates. Since over small increments of SOC the charging profile 13 has the same slope as the actual SOC-OCV curve, a charging slope vector compiled as an array of individual slope values over consecutive increments can be used to identify which of the family of SOC-OCV curves most closely matches the current battery cell condition without requiring an accurate measurement of the actual SOC. An increment 14 from an initial SOC value (SOC₀) at 15 to a final SOC value (SOC₁) at 16 together with corresponding cell voltage values define a slope value for a segment 17. A corresponding segment 18 of the SOC-OCV curve has the same slope value, but has a magnitude offset by an unknown amount. In the method of the invention, only the slope values are needed in order to identify the best SOC-OCV curve to be used.

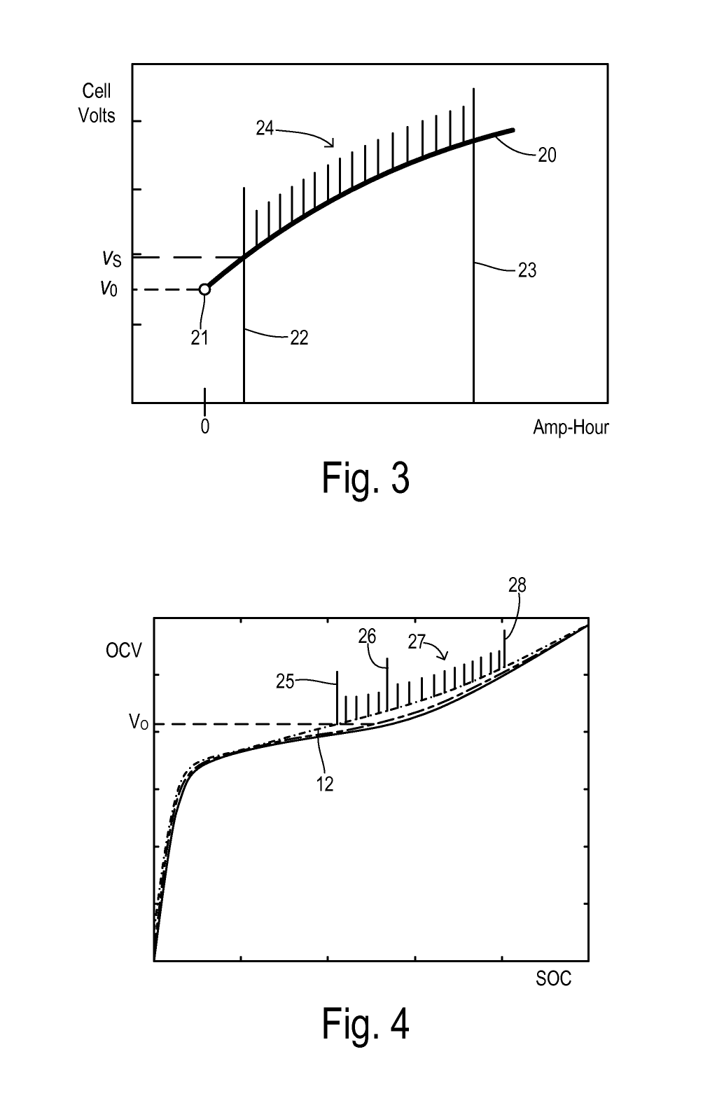

FIG. 3 shows the piecewise representation of the charging slope vector in greater detail. A charging curve 20 begins with zero amp-hours of recharging at a point 21, where an initial cell voltage v₀ is measured. Compiling a charging slope vector can begin immediately, but more preferably it can wait until an optimal charging condition occurs at 22 (when the cell voltage has increased to a starting voltage v_{S}). The corresponding charge flowing into the battery cell is AH₀ Amp-Hour. Factors that determine an optimal charging condition may include 1) ensuring substantially constant charging current, 2) charging current magnitude within a predetermined range where current sensing has its peak accuracy, making sure the change of open circuit voltage per SOC is small enough, and/or 3) battery temperature within a desirable range (e.g., ensuring the cell is not frozen). Until the optimal charging condition ends at 23, a plurality of slope values 24 are calculated and concatenated together to form the charging slope vector. For each respective increment (e.g., identified according to an index i), a slope value k is determined according to a formula:

$${k}_{i} = \frac{{v}_{t 1} - {v}_{t 0}}{{\int }_{{t}_{0}}^{{t}_{0} + t} i \cdot d t}$$

The value of index i increases as long as total charge accumulation continues to increase by the threshold amount. Each successive increment is measured from its beginning at a respective time t₀ to its respective completion at a time t₁, wherein time t₁ is detected as the time when the accumulating charge defined by the integral of i·dt reaches the Amp-Hour threshold (i.e., at a time t₀+t). The Amp-Hour threshold varies with the battery chemistries, and can be determined via laboratory testing. The Amp-Hour threshold should be big enough that increase of cell voltages respectively measured at time (t₀+t) and time t₀ is noticeable. For example, the Amp-Hour threshold could be be about 0.1 of the battery cell capacity. One criterion to select the Amp-Hour threshold is making sure that the internal resistance will not change significantly when the SOC change within the Amp-Hour threshold. Thus, each slope value is calculated from the cell voltages at the beginning and ending of an SOC increment and the Amp-Hour threshold (AH) as follows:

$${k}_{i} = \frac{{v}_{t 1} - {v}_{t 0}}{AH} .$$

In some embodiments, multiple Amp-Hour thresholds could be used according to different SOC ranges. For example, a small Amp-Hour threshold can be defined for a low SOC range from 0 to 0.2 of the battery cell capacity; a relatively big Amp-Hour threshold can be defined for a medium SOC range from 0.2 to 0.7 of the battery cell capacity; and a medium Amp-Hour threshold can be defined for a high SOC range from 0.8 to 1 of the battery cell capacity.

At the end of a charging cycle or anytime after sufficient slope values have been compiled for the charging slope vector, the resulting charging slope vector is compared to the stored family of SOC-OCV curves in a piecewise manner. Since storing both the SOC-OCV curves and all the potential slope values for all the starting and stopping cell voltage values would be impractical, slope vectors for all the SOC-OCV aging curves may preferably be calculated on the fly.

FIG. 4 shows a division of SOC-OCV curve again 12 into equivalent SOC increments referenced to initial cell voltage v₀ that is measured as an OCV prior to activating the battery charger. Slope values for curve 12 are calculated beginning with a first piecewise increment at 25 which is the point on curve 12 with an OCV value equal to measured v₀. In the event that the optimal charging condition did not exist at the beginning of charging as shown in FIG. 3, the slope values for curve 12 are not included in the SOC-OCV slope vector for curve 12 (i.e., not calculated) until reaching an increment 26 where the change in SOC from point 25 to point 26 equals the accumulated charge (i.e., total Amp-hours) from point 21 to point 22 AH₀ Amp-hours in FIG. 3. If the cell capacity Q is available, the corresponding OCV V_{S}^{OC} at point 26 is

$${V}_{S}^{OC} = {f}^{- 1} ( f ( {v}_{0} ) + \frac{{AH}_{0}}{Q} )$$

Then the slope values for curve 12 are determined for increments 27 until the corresponding end of the charging slope vector at point 28. Subsequently, each remaining SOC-OCV aging curve is processed to obtain their respective SOC-OCV slope vectors and then each one is compared with the charging slope vector to find a best fit as described in greater detail below.

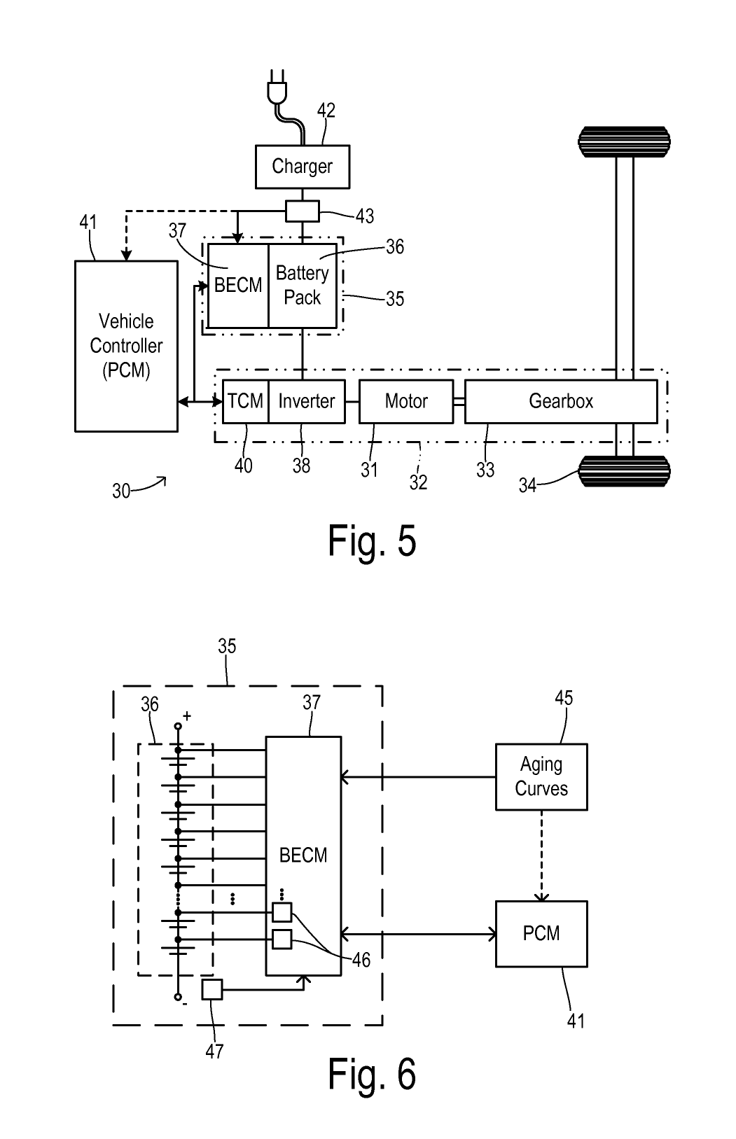

FIG. 5 shows one type of vehicle system in which the present invention can be implemented. In this case, a vehicle 30 is depicted as a battery electric vehicle (BEV) propelled by an electric motor 31 without assistance from an internal combustion engine. Motor 31 receives electrical power and provides drive torque for vehicle propulsion. Motor 31 also functions as a generator for converting mechanical power into electrical power through regenerative braking. Motor 31 is part of a powertrain 32 in which a gearbox 33 couples motor 31 to driven wheels 34. Gearbox 33 adjusts the drive torque and speed of motor 31 by a predetermined gear ratio.

Vehicle 30 includes a battery system 35 including a main battery pack 36 and a battery energy controller module (BECM) 37. An output of battery pack 36 is connected to an inverter 38 which converts the direct current (DC) power supplied by the battery to alternating current (AC) power for operating motor 31 in accordance with commands from a traction control module (TCM) 40. TCM 40 monitors, among other things, the position, speed, and power consumption of motor 31 and provides output signals corresponding to this information to other vehicle systems including a main vehicle controller 41 (which may be a powertrain control module, or PCM, for example).

An AC charger 42 is provided for charging main battery 36 from an external power supply (not shown), such as the AC power grid. A current sensor 43 measures the charging current and provides the resulting current measurement to BECM 37. Although vehicle 30 is shown as a BEV, the present invention is applicable to any electric vehicles using a multi-cell battery pack including HEVs and PHEVs.

FIG. 6 shows battery system 35 in greater detail wherein battery pack 36 is a multi-cell battery packaged together with BECM 37. Each individual cell of battery 36 is coupled to a respective sampling input of BECM 37. Each sampling input includes a respective sensing circuit 46 for determining the respective cell voltage and current. In addition, each battery cell may include a respective temperature sensor, such as temperature sensor 47, which may be comprised of a thermistor coupled with BECM 37. An electronic memory or storage 45 includes the predetermined plurality of aging curves for use by the BECM 37 and/or PCM 41. Memory 45 can be incorporated into either BECM 37 or PCM 41.

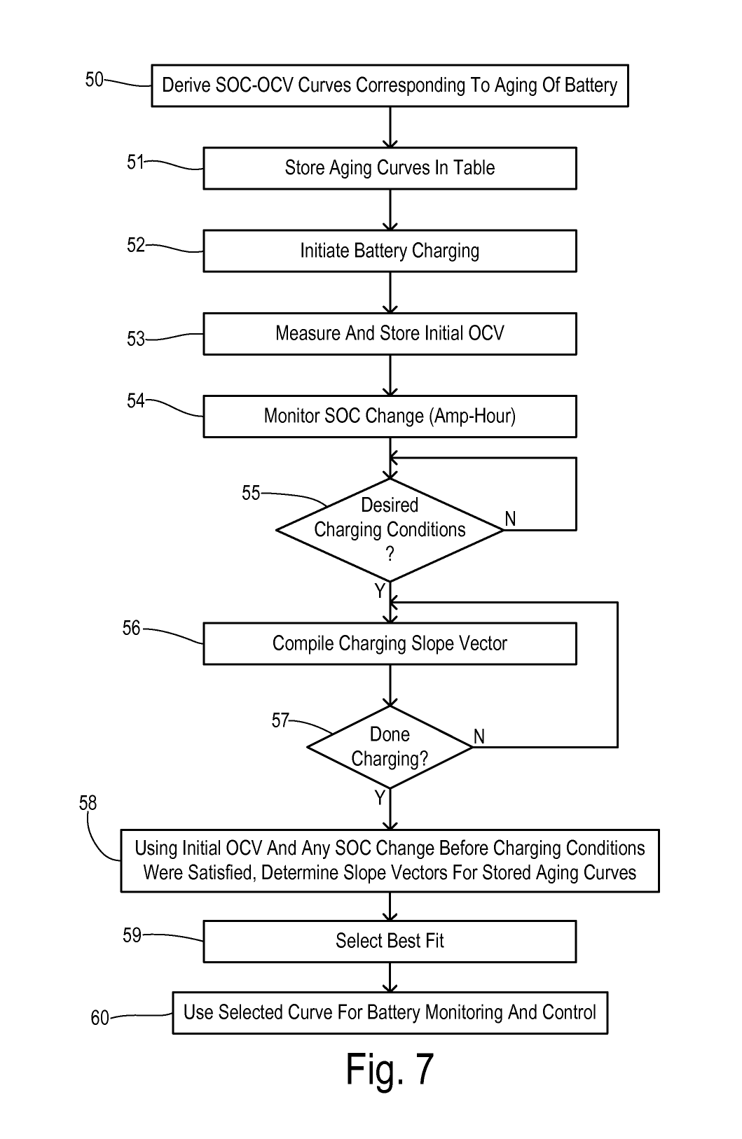

FIG. 7 shows a preferred method of the invention in greater detail. In step 50, a plurality of SOC-OCV curves corresponding to successive aging states of the battery are derived, e.g., under laboratory testing. The resulting aging curves are stored in a table in step 51 for inclusion in the electric vehicles incorporating the same battery design so that appropriate aging curves can be appropriately updated during vehicle use according to the present invention.

Throughout vehicle service, the present invention repeatedly monitors battery performance during charging in order to identify the appropriate aging curve. Battery charging is initiated in step 52. In step 53, an initial open circuit voltage for a battery cell is measured and stored. Since all battery cells can often be reasonably expected to perform in a similar manner, testing of just one battery cell may usually be sufficient to identify the appropriate aging curve. Otherwise, the method described herein can be employed with a plurality of battery cells as necessary.

During charging, the change in SOC is monitored in step 54 according to the accumulation of the amp-hour charging. In step 55, a check is made to determine whether desired optimal charging conditions are present. The desired charging condition preferably corresponds to the existence of a quasi-steady-state cell charging current (i.e., that remains stable within a predetermined calibrated range). For example, the quasi-steady-state current is defined as follows:

For a time>a calibrated time (e.g., 100 seconds), it is true that

abs(i)+Δi>abs(i)>abs(i)−Δi,

where Δi is a calibratable offset. In addition, the desired charging condition may include the requirement that the quasi-steady-state current remain in a preferred measurement range which includes a peak accuracy in the operation of the current sensor being used. As a fourth condition, the desired charging conditions may include a requirement that a cell temperature is within a predetermined range (e.g. a range that avoids undesirable cell conditions such as freezing). If desired charging conditions are not detected in step 55 then the conditions are periodically rechecked until the desired charging condition is obtained.

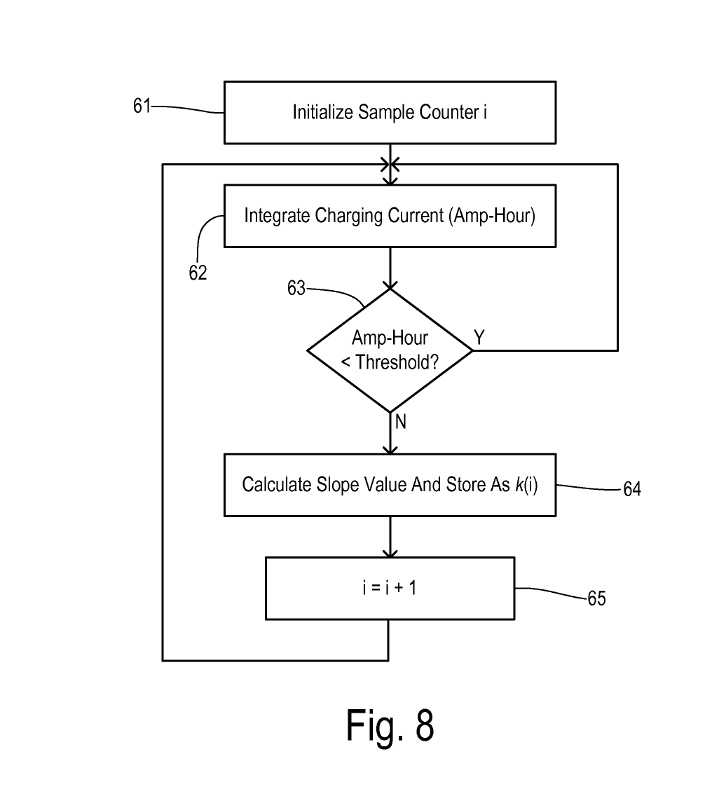

In step 56, a charging slope vector is compiled once the desired charging condition is present. Compilation of the charging slope vector may preferably be performed in accordance with a preferred method as shown in FIG. 8. A sample counter index i is initialized in step 61. The charging current is integrated as an aggregate amp-hour value in step 62. A check is performed in step 63 to determine whether the accumulated amp-hour value is less than the amp-hour threshold. If so then the integration of the charging current continues in step 62. Once the accumulated charge reaches the threshold, a slope value k(i) is calculated and stored in step 64. Calculation of the slope value proceeds by taking the difference of the cell voltages at the beginning and end of the SOC increment and then dividing by the amp-hour threshold (i.e., the increase in SOC). The index counter i is incremented in step 65, and a return is made to step 62 to integrate the charging current to detect the next successive SOC increment.

Returning to FIG. 7, as the charging slope vector continues to be compiled in step 56, a check is performed in step 57 to determine whether charging is completed. Once it is completed, processing of the aging curves begins in step 58. Using an initial OCV value and any SOC change that may have occurred before the charging conditions were satisfied, SOC-OCV slope vectors are determined for the stored aging curves. For each SOC-OCV slope vector j (where j goes from 1 to J, the number of curves in storage), the plurality of slope values in vector j are defined as follows:

$${s}_{j} [ i ] = \frac{( {v}_{j , i , 1}^{OC} - {v}_{j , i , 2}^{OC} )}{AH}$$

where v_{j,i,1}^{OC} is the OCV based on jth SOC-OCV curve corresponding to the beginning of the ith linear piece, and v_{j,i,2}^{OC} is the OCV based on jth SOC-OCV curve corresponding to the end of the ith linear piece. The v_{j,i,1}^{OC} and v_{j,i,1}^{OC} are calculated by

V_{j,i,1}^{OC}=V_{S}^{OC}

V_{j,i,1}^{OC}=V_{j,i-1,2}^{OC}i>2

$${V}_{j , i , 2}^{OC} = {f}_{j}^{- 1} ( {f}_{j} ( {V}_{j , i , 1}^{OC} ) + \frac{AH}{Q} )$$

where Q is the battery capacity, and fⱼ(•) is the jth SOC-OCV curve stored in the SOC-OCV curves bank. Once all the stored aging curves have been processed to provide respective SOC-OCV slope vectors, they are each compared to the charging slope vector in order to select a best fit in step 59. The comparison may preferably be performed using a squared Euclidian distance of the respective slope values as follows:

$$( {\sum }_{i} {( k [ i ] - {s}_{j} [ i ] )}^{2} )$$

The SOC-OCV curve with the best fit is one with the minimal distance, e.g.

$${MIN}_{j} ( {\sum }_{i} {( k [ i ] - {s}_{j} [ i ] )}^{2} )$$

It should be noted that some other similarity measures can also be used to compare the charging slope vector and the SOC-OCV slope vectors. For example, it is usual that every slope in the slope vector has different significance to compare the charging curve and the SOC-OCV curve. Thus, the weighted squared Euclidian distance is a nice choice for comparison, e.g.,

$$( {\sum }_{i} {w}_{j} \times {( k [ i ] - {s}_{j} [ i ] )}^{2} ) , 0 \leq {w}_{j} \leq 1 and {\sum }_{j} {w}_{j} = 1$$

where wⱼ are some significance factor. The slope, which has great significance in comparison, has a greater weight. The SOC-OCV curve with the best fit is the one which can minimize following objective:

$${MIN}_{j} ( {\sum }_{i} {w}_{j} \times {( k [ i ] - {s}_{j} [ i ] )}^{2} ) .$$

The SOC-OCV slope vector for j satisfying the minimum becomes the selected SOC-OCV curve. The selected curve is then used for battery monitoring and control in step 60. The monitoring of the battery includes the ability to obtain a more accurate estimate of the actual SOC of the battery. The selected SOC-OCV curve also enables better estimation of the battery capacity and battery power capability as it ages.

As is apparent from FIG. 1, the drifts that occur in the SOC-OCV relationship are generally not linear (i.e., affect different SOC ranges differently). Therefore, the slope changes unambiguously identify the desired one of the curves. In the event that two or more curves had significant regions with identical slopes, the correct curve can still be identified using a cell terminal voltage measurement. This can be done by 1) for the same charging current at the same SOC, find the magnitude of the shifting of the cell terminal voltage, and then 2) SOC-OCV curve with the same magnitude OCV shift at the same SOC should be selected.

What is claimed is:

1. A method of monitoring a battery cell using open circuit voltage (OCV), comprising:
charging the battery cell;
detecting a charging condition in response to a predetermined charging current;
measuring OCV during battery cell usage following charging; and
converting measured OCV values to battery cell SOC values using a selected stored SOC-OCV aging curves having an SOC-OCV slope vector best fitting a charging slope vector, wherein the selected SOC-OCV aging curve is selected based on a) a charging slope vector compiled during the charging condition comprising a plurality of slope values over respective state-of-charge (SOC) increments, and b) a plurality of SOC-OCV slope vectors corresponding to a plurality of stored SOC-OCV aging curves, each SOC-OCV slope vector comprising a plurality of slope values over equivalent state-of-charge increments.

2. The method of claim 1 wherein the respective state-of-charge increments are detected in response to a predetermined ampere-hour charge increase.

3. The method of claim 1 further comprising:
measuring an open circuit voltage of the battery cell prior to applying the charging current;
wherein each of the SOC-OCV slope vectors has a starting value determined in response to the measured open circuit voltage.

4. The method of claim 1 wherein the best fitting SOC-OCV slope vector is determined according to a best fit by least sum of squares of the slope values.

5. The method of claim 1 wherein the predetermined charging current is detected as a quasi-steady state current maintained within a predetermined range for a predetermined time.

6. The method of claim 5 wherein the predetermined range corresponds to a peak accuracy for sensing the charging current.

7. The method of claim 1 wherein the charging condition is further detected in response to a predetermined temperature range.

8. An electric vehicle, comprising:
a multi-cell battery;
a battery charger;
a controller compiling a charging slope vector comprising slope values over respective state-of-charge increments, compiling a plurality of SOC-OCV slope vectors for stored SOC-OCV aging curves over equivalent state-of-charge increments, and selecting one of the stored SOC-OCV aging curves having an SOC-OCV slope vector best fitting the charging slope vector for use in converting measured OCV values to battery cell SOC values.

9. The electric vehicle of claim 8 further comprising a current sensor for measuring a charging current, wherein the respective state-of-charge increments are detected in response to a predetermined ampere-hour charge increase based on the measured charging current.

10. The electric vehicle of claim 8 further comprising a voltage sensor for measuring an open circuit voltage of a battery cell prior to charging, wherein each of the SOC-OCV slope vectors has a starting value obtained in response to the measured open circuit voltage.

11. The electric vehicle of claim 8 wherein the best fitting SOC-OCV slope vector is identified according to a best fit by minimal squared Euclidian distance of the slope values.

12. The electric vehicle of claim 8 wherein the best fitting SOC-OCV slope vector is identified according to a best fit by minimal weighted squared Euclidian distance of the slope values using significance of each slope.

13. The electric vehicle of claim 8 further comprising a current sensor for measuring a charging current, wherein the charging slope vector is compiled when a predetermined charging current is detected as a quasi-steady state current maintained within a predetermined range for a predetermined time.

14. The electric vehicle of claim 13 wherein the predetermined range corresponds to a peak accuracy of the current sensor.

15. The electric vehicle of claim 8 further comprising a temperature sensor measuring a temperature of the battery, wherein the charging slope vector is compiled when the measured temperature is within a predetermined temperature range.

16. A method of monitoring battery state-of-charge (SOC) comprising:
charging the battery;
compiling a charging slope vector comprising slope values over respective state-of-charge increments;
compiling a plurality of SOC-OCV slope vectors for stored SOC-OCV aging curves over equivalent state-of-charge increments; and
selecting one of the stored SOC-OCV aging curves having an SOC-OCV slope vector best fitting the charging slope vector for use in converting measured OCV values to battery SOC values.
